(19) United States
(12) Patent Application Publication
(10) Pub. No.: US 2019/0133004 A1
(43) Pub. Date: May 2, 2019

(54) SHIELDING CASE

(71) Applicant: PEGATRON CORPORATION, TAIPEI CITY (TW)

(72) Inventor: Chih-Chung Lai, Taipei City (TW)

(73) Assignee: PEGATRON CORPORATION, TAIPEI CITY (TW)

(21) Appl. No.: 16/160,839

(22) Filed: Oct. 15, 2018

(30) Foreign Application Priority Data
Nov. 2, 2017 (TW) 106216253

(51) Int. Cl. H05K 9/00

(52) U.S. Cl. CPC H05K 9/0049; H05K 9/0081

(57) ABSTRACT

A shielding case includes a first casing, a second casing, a first electromagnetic shielding layer, and a second electromagnetic shielding layer. The second casing is disposed at the first casing to be opened or closed with respect to the first casing. The first electromagnetic shielding layer is disposed at the first casing. The second electromagnetic shielding layer is disposed at the second casing. When the first casing and the second casing are in a closed state, an accommodating space is formed between the first casing and the second casing, and the accommodating space is surrounded by the first electromagnetic shielding layer and the second electromagnetic shielding layer.

### CROSS REFERENCE TO RELATED APPLICATION

This application claims the priority benefit of Taiwanese application serial no. 106216253, filed on Nov. 2, 2017. The entirety of the above-mentioned patent application is hereby incorporated by reference herein and made a part of specification.

### BACKGROUND

### Field of the Invention

The disclosure relates to a shielding case, and in particular, to a shielding case capable of reducing noise interference to signals in radio frequency (RF) cable.

### Description of Related Art

The RF cable is an electronic component commonly used in the communication field. Generally, the RF cable includes coaxial terminals that are engaged or joined with an electronic device to be connected to or a corresponding cable. However, after the RF cable has been over used and plugged too many times, the connected portion of the coaxial terminals and the electronic device or the corresponding cable cannot tightly fit together, such that noise may easily get through it and affect the quality of signal transmission.

### SUMMARY

The invention provides a shielding case that covers male and female connectors connected to each other to reduce noise and thereby improve quality of signal transmission and can be repeatedly used.

A shielding case of the invention includes a first casing, a second casing, a first electromagnetic shielding layer, and a second electromagnetic shielding layer. The second casing is disposed at the first casing to be opened or closed with respect to the first casing. The first electromagnetic shielding layer is disposed at the first casing. The second electromagnetic shielding layer is disposed at the second casing. When the first casing and the second casing are in a closed state, an accommodating space is foiiiied between the first casing and the second casing, and the accommodating space is surrounded by the first electromagnetic shielding layer and the second electromagnetic shielding layer.

In an embodiment of the invention, the first casing has a first side and a second side away from each other, and the second casing has a third side and a fourth side away from each other. The first side of the first casing is pivotally connected to the third side of the second casing, and the second side of the first casing is detachably fixed to the fourth side of the second casing.

In an embodiment of the invention, the first casing includes a first fixing part located on the second side. The second casing includes a second fixing part located on the fourth side and corresponding to the first fixing part. One of the first fixing part and the second fixing part is a hook, and the other one is a tenon.

In an embodiment of the invention, the first casing has a first side and a second side away from each other. The second casing has a third side and a fourth side away from each other. The first side of the first casing is detachably fixed to the third side of the second casing, and the second side of the first casing is detachably fixed to the fourth side of the second casing.

In an embodiment of the invention, the first casing includes a first fixing part located on the first side and a second fixing part located on the second side. The second casing includes a third fixing part located on the third side and corresponding to the first fixing part and a fourth fixing part located on the fourth side and corresponding to the second fixing part. One of the first fixing part and the third fixing part is a hook, and the other one is a tenon, and one of the second fixing part and the fourth fixing part is a hook, and the other one is a tenon.

In an embodiment of the invention, the first electromagnetic shielding layer is disposed on an inner surface or an outer surface of the first casing or is buried inside the first casing. The second electromagnetic shielding layer is disposed on an inner surface or an outer surface of the second casing or is buried inside the second casing.

In an embodiment of the invention, at least one of the first electromagnetic shielding layer and the second electromagnetic shielding layer is a metal layer.

In an embodiment of the invention, at least one of the first electromagnetic shielding layer and the second electromagnetic shielding layer is an electromagnetic wave-absorbing layer.

In an embodiment of the invention, the first casing and the second casing are made of insulating materials.

A shielding case of the invention includes a first electromagnetic shielding casing and a second electromagnetic shielding casing. The second electromagnetic shielding casing is disposed at the first electromagnetic shielding casing to be opened or closed with respect to the first electromagnetic shielding casing. When the first electromagnetic shielding casing and the second electromagnetic shielding casing are in a closed state, an accommodating space is formed between the first electromagnetic shielding casing and the second electromagnetic shielding casing, and the accommodating space is surrounded by the first electromagnetic shielding casing and the second electromagnetic shielding casing.

In an embodiment of the invention, at least one of the first electromagnetic shielding casing and the second electromagnetic shielding casing is a metal casing.

In an embodiment of the invention, at least one of the first electromagnetic shielding casing and the second electromagnetic shielding casing is a casing made of an electromagnetic wave-absorbing material.

To provide a further understanding of the aforementioned and other features and advantages of the disclosure, exemplary embodiments, together with the reference drawings, are described in detail below.

### BRIEF DESCRIPTION OF THE DRAWINGS

FIG. 1 is a perspective schematic diagram illustrating a shielding case in a closed state according to an embodiment of the invention.

FIG. 2 and FIG. 3 are perspective schematic diagrams illustrating the shielding case shown in FIG. 1 in an open state from respective viewing angles.

FIG. 4 is a cross-sectional diagram illustrating the shielding case shown in FIG. 2 along line segment A-A.

FIG. 5 is a cross-sectional diagram illustrating the shielding case shown in FIG. 1 covering two connectors connected to each other.

FIG. 6 is a cross-sectional diagram illustrating a shielding case according to another embodiment of the invention.

FIG. 7 is a cross-sectional diagram illustrating a shielding case according to another embodiment of the invention.

FIG. 8 is a cross-sectional diagram illustrating a shielding case according to another embodiment of the invention.

FIG. 9 is a perspective schematic diagram illustrating a shielding case in a disassembled state according to another embodiment of the invention.

### DETAILED DESCRIPTION

The foregoing and other technical content, features, and effects of the invention will be clearly presented in the following detailed description of the embodiments with reference to the reference drawings. Directional terminology, such as “upper”, “lower”, “left”, “right”, “front”, “back”, etc., mentioned in the embodiments below is used with reference to the orientation of the drawings attached. Accordingly, the directional terminology used will be regarded as illustrating rather than limiting the invention. Moreover, in the embodiments below, the same or similar components will be labeled with the same or similar reference numerals.

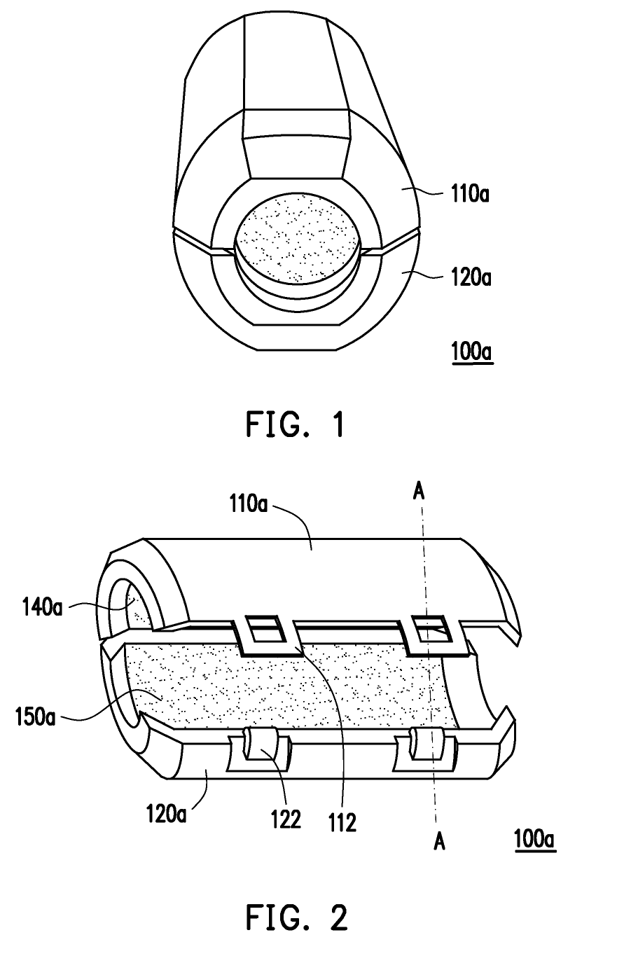

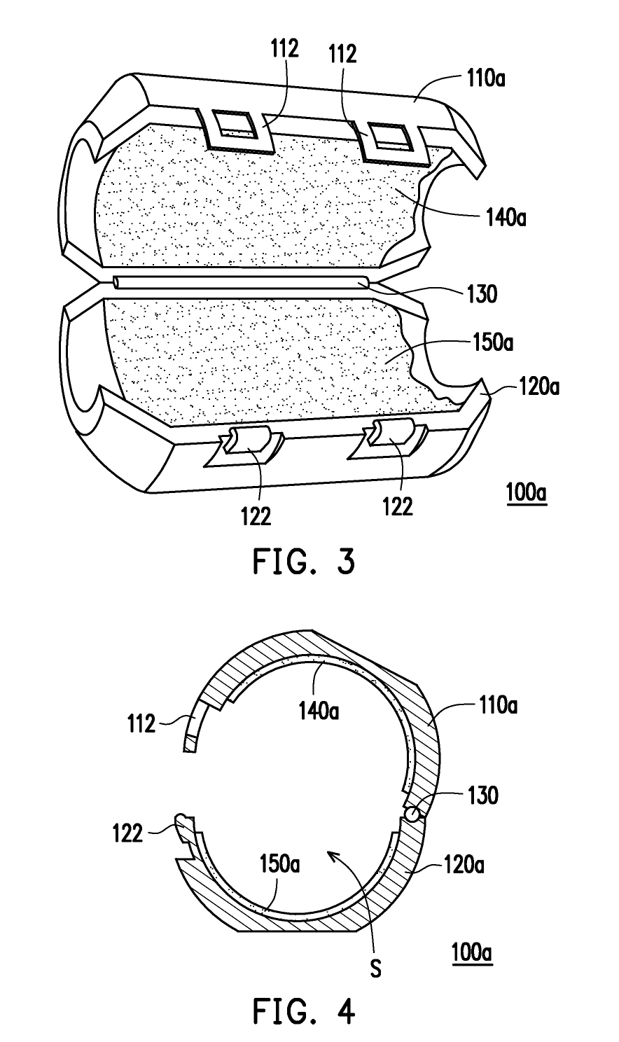

FIG. 1 is a perspective schematic diagram illustrating a shielding case in a closed state according to an embodiment of the invention. FIG. 2 and FIG. 3 are perspective schematic diagrams illustrating the shielding case shown in FIG. 1 in an open state from respective viewing angles. Referring to FIG. 1, FIG. 2, and FIG. 3, a shielding case 100a of the present embodiment includes a first casing 110a, a second casing 120a, a first electromagnetic shielding layer 140a, and a second electromagnetic shielding layer 150a. The second casing 120a is disposed at the first casing 110a to be opened or closed with respect to the first casing 110a. The first electromagnetic shielding layer 140a is disposed at the first casing 110a. The second electromagnetic shielding layer 150a is disposed at the second casing 120a.

To be specific, the first casing 110a of the present embodiment has a first side and a second side away from each other and the second casing 120a has a third side and a fourth side away from each other. The first side of the first casing 110a is pivotally connected to the third side of the second casing 120a via a pivotal connection part 130, and the second side of the first casing 110a is detachably fixed to the fourth side of the second casing 120a. The pivotal connection part 130 is, for example, a hinge but may be another structure having a pivotal connection function, and the invention is not limited hereto.

Moreover, in the present embodiment, the first casing 110a includes a first fixing part 112 located on the second side, and the second casing 120a includes a second fixing part 122 located on the fourth side corresponding to the first fixing part 112. One of the first fixing part 112 and the second fixing part 122 is a hook, and the other one is a tenon. To be specific, the first fixing part 112 and the second fixing part 122 are arranged so that the shielding case 100a is not loosened during operation. In the present embodiment, the number of each of the first fixing part 112 and the second fixing part 122 is two. However, the types of the first fixing part 112 and the second fixing part 122 are not limited hereto. In other embodiments, the method of fixing the first fixing part 112 and the second fixing part 122 to each other may also involve adhesion, splicing, or linking. The corresponding type and number of each of the first fixing part 112 and the second fixing part 122 is not particularly limited herein. As long as they can achieve the effect of fixing the first casing 110a and the second casing 120a to each other, they all fall in the scope of the present invention.

As shown in FIG. 3, the first electromagnetic shielding layer 140a is disposed on an inner surface of the first casing 110a, and the second electromagnetic shielding layer 150a is disposed on an inner surface of the second casing 120a. In the present embodiment, at least one of the first electromagnetic shielding layer 140a and the second electromagnetic shielding layer 150a is a metal layer. Certainly, they may include other electromagnetic wave-absorbing materials having shielding effect to shield against noise outside the shielding case 100a. Moreover, the first casing 110a and the second casing 120a are made of an insulating material in order to prevent a user from getting shocked caused by the static electricity on the first electromagnetic shielding layer 140a or the second electromagnetic shielding layer 150a when the user is operating the shielding case 100a.

It is noted that the first casing 110a and the second casing 120a may be made of respective materials, and the first electromagnetic shielding layer 140a and the second electromagnetic shielding layer 150a may also be made of respective materials, as long as they both achieve the effects of isolating the static electricity and blocking the external noise.

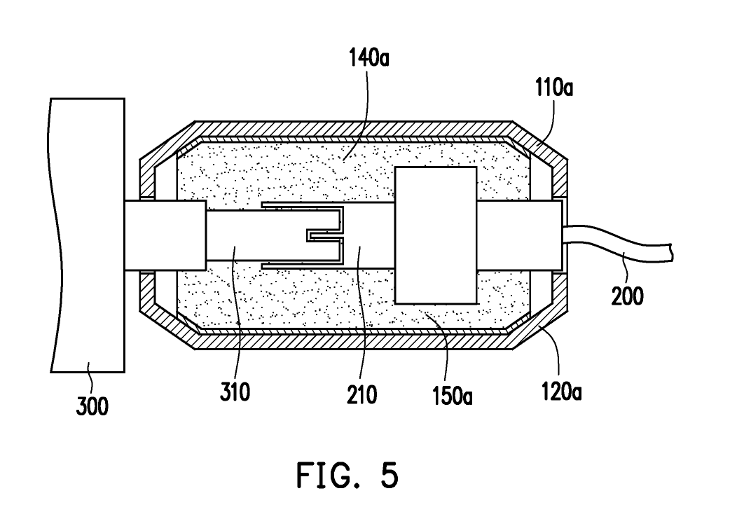

FIG. 4 is a cross-sectional diagram illustrating the shielding case shown in FIG. 2 along line segment A-A. FIG. 5 is a cross-sectional diagram illustrating the shielding case shown in FIG. 1 covering two connectors connected to each other. Referring to FIG. 4 and FIG. 5, in the present embodiment, a radio frequency (RF) cable 200 is adapted to be electrically connected to an electronic device 300. Specifically, the RF cable 200 includes a first connection part 210, the electronic device 300 includes a second connection part 310, and the RF cable 200 is connected to the second connection part 310 of the electronic device 300 via the first connection part 210. After the RF cable 200 is connected to the electronic device 300, the user may mount the shielding case 100a of the present embodiment onto the first connection part 210 and the second connection part 310 and fix the first casing 110a and the second casing 120a to each other by the first fixing part 112 and the second fixing part 122.

Specifically, when the first casing 110a and the second casing 120a are in the closed state, an accommodating space S is formed between the first casing 110a and the second casing 120a, and the accommodating space S is surrounded by the first electromagnetic shielding layer 140a and the second electromagnetic shielding layer 150a. More specifically, the user may align the first electromagnetic shielding layer 140a with the upper portions of the first connection part 210 of the RF cable 200 and the second connection part 310 of the electronic device 300, and align the second electromagnetic shielding layer 150a with the lower portions of the first connection part 210 of the RF cable 200 and the second connection part 310 of the electronic device 300, and then engage the tenon of the second fixing part 122 with the hook of the first fixing part 112, such that the first connection part 210 and the second connection part 310 are located inside the accommodating space S. Since the first electromagnetic shielding layer 140a and the second electromagnetic shielding layer 150a are fonned of the metal or electromagnetic wave-absorbing material having the shielding effect, they can block the noise from the outside of the shielding case 100a, reduce the amount of noise entering the first connection part 210 and the second connection part 310 configured to connect the RF cable 200 and the electronic device 300, and thereby improve the quality of signal transmission of the RF cable 200. Moreover, when the RF cable 200 is not in use, the user may disengage the first fixing part 112 from the second fixing part 122 to separate the first casing 110a from the second casing 120a and remove the shielding case 100a from the first connection part 210 and the second connection part 310. Accordingly, the shielding case 100a may be repeatedly used in many different RF cables.

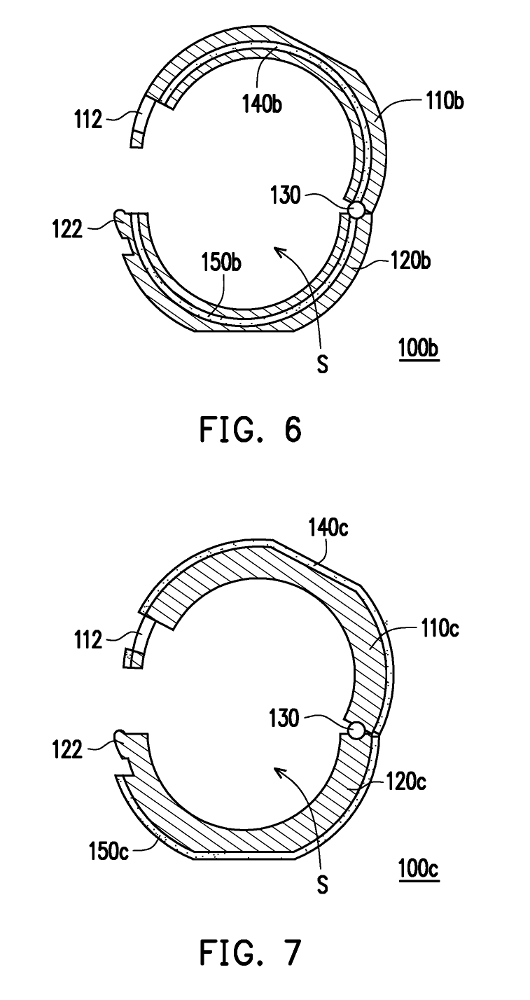

FIG. 6 is a cross-sectional diagram illustrating a shielding case according to another embodiment of the invention. Referring to both FIG. 4 and FIG. 6, a shielding case 100b of the present embodiment is similar to the shielding case 100a of FIG. 4, and the difference between the two lies in that a first electromagnetic shielding layer 140b of the shielding case 100b of the present embodiment is buried inside a first casing 110b, and a second electromagnetic shielding layer 150b is buried inside a second casing 120b. In other words, the first electromagnetic shielding layer 140b is covered by the first casing 110b, and the second electromagnetic shielding layer 150b is covered by the second casing 120b. Accordingly, the shielding case 100b can achieve the same noise shielding effect as the shielding case 100a. Moreover, when the user touches the inside of the shielding case 100b with his/her bare hands, with the arrangement of burying the first electromagnetic shielding layer 140b inside the first casing 110b and burying the second electromagnetic shielding layer 150b inside the second casing 120b, the user does not directly touch the first electromagnetic shielding layer 140b or the second electromagnetic shielding layer 150b.

FIG. 7 is a cross-sectional diagram illustrating a shielding case according to another embodiment of the invention. Referring to both FIG. 4 and FIG. 7, a shielding case 100c of the present embodiment is similar to the shielding case 100a of FIG. 4, and the difference between the two lies in that a first electromagnetic shielding layer 140c of the shielding case 100c of the present embodiment is disposed on an outer surface a first casing 110c, and a second electromagnetic shielding layer 150c is disposed on an outer surface of a second casing 120c. Accordingly, an accommodating space S larger than that of the shielding case 100a is formed according to an embodiment of the present invention even if the shielding case 100c has the same sizes of the first casing 110c and the second casing 120c as the shielding case 100a does. Thereby, the shielding case 100c is applicable to more types and sizes of RF cables and achieves the same noise shielding effect as the shielding case 100a.

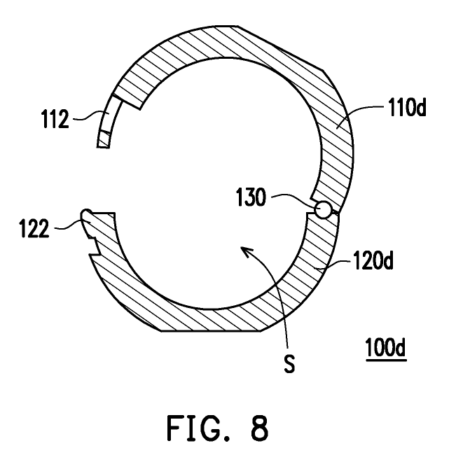

FIG. 8 is a cross-sectional diagram illustrating a shielding case according to another embodiment of the invention. Referring to both FIG. 4 and FIG. 8, a shielding case 100d of the present embodiment is similar to the shielding case 100a of FIG. 4, and the difference between the two lies in that the shielding case 100d of the present embodiment is directly formed by a first electromagnetic shielding casing 110d and a second electromagnetic shielding casing 120d. For example, the first electromagnetic shielding casing 110d may be a metal casing or a casing made of an electromagnetic wave-absorbing material having shielding effect, and the second electromagnetic shielding casing 120d may be a metal casing or a casing made of an electromagnetic wave-absorbing material having shielding effect. Accordingly, the shielding case 100d of the present embodiment skips the process of disposing the first electromagnetic shielding layer and the second electromagnetic shielding layer at the first casing and the second casing, such that the shielding case 100d has a simpler manufacturing process than the shielding case 100a and achieves the same noise shielding effect as the shielding case 100a.

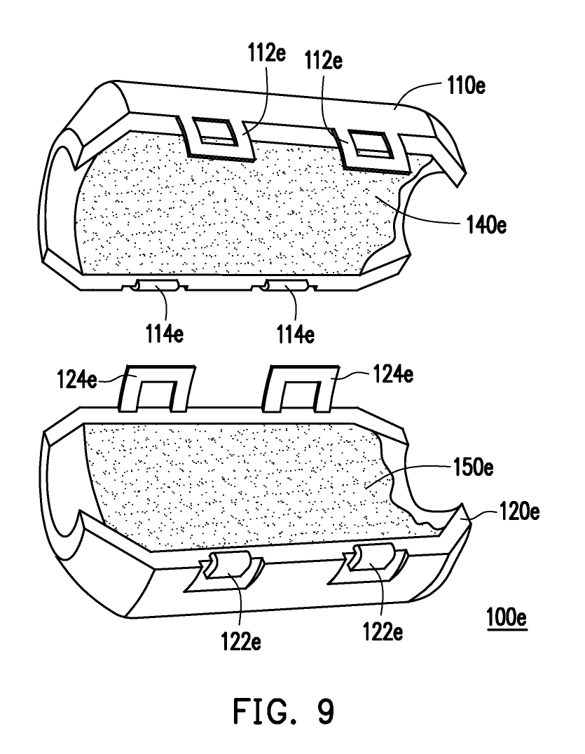

FIG. 9 is a perspective schematic diagram illustrating a shielding case in a disassembled state according to another embodiment of the invention. Referring to both FIG. 3 and FIG. 9, a shielding case 100e of the present embodiment is similar to the shielding case 100a of FIG. 3, and the difference between the two lies in that, in the shielding case 100e of the present embodiment, the first side of a first casing 110e is detachably fixed to the third side of a second casing 120e, and the second side of the first casing 110e is detachably fixed to the fourth side of the second casing 120e. Specifically, the first casing 110e includes a first fixing part 112e located on the first side and a second fixing part 114e located on the second side. The second casing 120e includes a third fixing part 122e located on the third side corresponding to the first fixing part 112e and a fourth fixing part 124e located on the fourth side corresponding to the second fixing part 114e. In the present embodiment, one of the first fixing part 112e and the third fixing part 122e is a hook, and the other one is a tenon. One of the second fixing part 114e and the fourth fixing part 124e is a hook, and the other one is a tenon.

Furthermore, the first casing 110e and the second casing 120e may freely move with respect to each other. When the user intends to operate the shielding case 100e in coordination with an RF cable, the tenon of the third fixing part 122e of the second casing 120e may be engaged with the hook of the first fixing part 112e of the first casing 110e, and the tenon of the second fixing part 114e of the first casing 110e may be engaged with the hook of the fourth fixing part 124e of the second casing 120e, such that the connected portion of the RF cable and the electronic device is located in an accommodating space formed between the first casing 110e and the second casing 120e and surrounded by a first electromagnetic shielding layer 140e and a second electromagnetic shielding layer 150e. Accordingly, the shielding case 100e can achieve the same noise shielding effect as the shielding case 100a. Moreover, since the structures of the first casing 110e and the second casing 120e are geometrically identical, the first casing 110e and the second casing 120e may be manufactured by using one single production mold, which saves the time and costs for designing and manufacturing molds for different casings.

It is noted that, in the present embodiment, the first fixing part 112e and the third fixing part 122e, and the fourth fixing part 124e and the second fixing part 122e are corresponding hooks and tenons, and the number of each part is two. However, the types of the first fixing part 112e, the second fixing part 114e, the third fixing part 122e, and the fourth fixing part 124e are not limited hereto. In other embodiments, the method of fixing the first fixing part 112e and the third fixing part 122e to each other and fixing the second fixing part 114e and the fourth fixing part 124e to each other may also involve adhesion, splicing, or linking. The corresponding type and number of each of the first fixing part 112e, the second fixing part 114e, the third fixing part 122e, and the fourth fixing part 124e is not specifically limited herein. As long as they can achieve the effect of fixing the first casing 110e and the second casing 120e to each other, they all fall in the scope of the invention.

In an actual test on electromagnetic wave values of a conventional RF cable before and after being covered by the shielding case 100a, the power of the detected noise was about −84.744 dBm before the RF cable was covered by the shielding case 100a when the RF cable was connected to a spectrum analyzer and was input with a signal having a frequency of 2.448 GHz.

On the other hand, when the RF cable was covered by the shielding case 100a and was connected with the signal having the same frequency range, the power of the noise detected by the spectrum analyzer was reduced to −96.709 dBm, which was 1/10 or less of the value detected in normal use. Accordingly, the shielding case of the invention can effectively reduce the impact of the external noise on signal transmission of the RF cable.

In summary of the above, with the accommodating space formed by the first electromagnetic shielding layer and the second electromagnetic shielding layer or the accommodating space formed by the first electromagnetic shielding casing and the second electromagnetic shielding casing, the shielding case of the invention blocks the noise from the outside of the shielding case, reduces the possibility of the noise entering and exiting the shielding case, and may be repeatedly used.

Although the invention is disclosed as the embodiments above, the embodiments are not meant to limit the invention. Any person skilled in the art may make slight modifications and variations without departing from the spirit and scope of the invention. Therefore, the protection scope of the invention shall be defined by the claims attached below.

What is claimed is:

1. A shielding case comprising:
a first casing;
a second casing disposed at the first casing to be opened or closed with respect to the first casing;
a first electromagnetic shielding layer disposed at the first casing; and
a second electromagnetic shielding layer disposed at the second casing, wherein an accommodating space is formed between the first casing and the second casing when the first casing and the second casing are in a closed state, and the accommodating space is surrounded by the first electromagnetic shielding layer and the second electromagnetic shielding layer.

2. The shielding case according to claim 1, wherein the first casing has a first side and a second side away from each other, the second casing has a third side and a fourth side away from each other, the first side of the first casing is pivotally connected to the third side of the second casing, and the second side of the first casing is detachably fixed to the fourth side of the second casing.

3. The shielding case according to claim 2, wherein the first casing comprises a first fixing part located on the second side, the second casing comprises a second fixing part located on the fourth side and corresponding to the first fixing part, one of the first fixing part and the second fixing part is a hook, and the other one is a tenon.

4. The shielding case according to claim 1, wherein the first casing has a first side and a second side away from each other, the second casing has a third side and a fourth side away from each other, the first side of the first casing is detachably fixed to the third side of the second casing, and the second side of the first casing is detachably fixed to the fourth side of the second casing.

5. The shielding case according to claim 4, wherein the first casing comprises a first fixing part located on the first side and a second fixing part located on the second side, the second casing comprises a third fixing part located on the third side and corresponding to the first fixing part and a fourth fixing part located on the fourth side and corresponding to the second fixing part, one of the first fixing part and the third fixing part is a hook, and the other one is a tenon, and one of the second fixing part and the fourth fixing part is a hook, and the other one is a tenon.

6. The shielding case according to claim 1, wherein the first electromagnetic shielding layer is disposed on an inner surface or an outer surface of the first casing or is buried inside the first casing, and the second electromagnetic shielding layer is disposed on an inner surface or an outer surface of the second casing or is buried inside the second casing.

7. The shielding case according to claim 1, wherein at least one of the first electromagnetic shielding layer and the second electromagnetic shielding layer is a metal layer.

8. The shielding case according to claim 1, wherein at least one of the first electromagnetic shielding layer and the second electromagnetic shielding layer is an electromagnetic wave-absorbing layer.

9. The shielding case according to claim 1, wherein the first casing and the second casing are made of insulating materials.

10. A shielding case, comprising:
a first electromagnetic shielding casing; and
a second electromagnetic shielding casing, disposed at the first electromagnetic shielding casing to be opened or closed with respect to the first electromagnetic shielding casing, wherein
when the first electromagnetic shielding casing and the second electromagnetic shielding casing are in a closed state, an accommodating space is fonned between the first electromagnetic shielding casing and the second electromagnetic shielding casing, and the accommodating space is surrounded by the first electromagnetic shielding casing and the second electromagnetic shielding casing.

11. The shielding case according to claim 10, wherein at least one of the first electromagnetic shielding casing and the second electromagnetic shielding casing is a metal casing.

12. The shielding case according to claim 10, wherein at least one of the first electromagnetic shielding casing and the second electromagnetic shielding casing is a casing made of an electromagnetic wave-absorbing material.
